(19) United States
(12) Patent Application Publication
(10) Pub. No.: US 2004/0052117 A1
(43) Pub. Date: Mar. 18, 2004

(54) Fabrication of ultra-small memory elements

(76) Inventor: Hai Jiang, Fremont, CA (US)

Correspondence Address: Hai Jiang, 46710 Crawford St. #6, Fremont, CA, 94539, US

(21) Appl. No.: 10/609,157

(22) Filed: Jun. 27, 2003

Related U.S. Application Data
(60) Provisional application No. 60/394,139, filed on Jul. 5, 2002.

(51) Int. Cl. G11C 29/00

(52) U.S. Cl. 365/200

(57) ABSTRACT

The memory elements with ultra-small resistive element are fabricated by filling the resistive element material in a nano-size opening. To make nano-size opening, a layer of composite-phase thin film is formed where a phase forms nano-size particles and embedded in another phase which forms a matrix layer. Then the nano-size opening was formed by etching the nano-size particles.

### CROSS-REFERENCE TO RELATED APPLICATIONS

This application claims benefit to PPA # 60/394,139 filed by Jul. 5, 2002 by the present inventor.

### FEDERALLY SPONSORED RESEARCH

None

### FIELD OF THE INVENTION

The present invention relates generally to semiconductor fabricating techniques, and more particularly to a method to make ultra-small size memory element such as, for example, phase-change resistive memory and programming metallization cell memory (PMCm)

### THE BACKGROUND OF THE INVENTION

In the recent years, a great deal of effect has been devoted to develop various non-volatile resistive memories. Generally, this kind of memory consists of a resistive element which is located between two electrodes. The resistive element can switch in different resistance values (or states) by a programming pulse current to realize the storage of the information. Two typical memories of using the resistive element to store the information are the electrically erasable phase change memory (herein we call it phase-change memory) and programming metallization cell memory (PMCm). In both of these memories, the resistive element material is made by filling resistive element material in an opening which is normally formed in a dielectric layer, while the dielectric layer is sandwiched in the electrodes. The resistive element contacts with the electrodes and constitutes a resistor. After the programming current flows through the resistive element, the resistance of the resistive element is changed and thus the information is stored.

In the phase-change memory, the resistive element is made of phase-change material. A typical of phase-change memory is chalcogenide phase-change memory which uses chalcogenide semiconductor as resistive element material (U.S. Pat. No. 3,530,441). The resistance value of the memory switches through the different atomic configuration in the resistive element, from the high resistance in a generally amorphous to a low resistance in a generally crystalline state, while the atomic configuration of the resistive element was changed by the heating effect from the programming pulse current. Therefore, the programming energy is directly proportional to the volume of the resistive element or the phase-change material.

The PMCm memory uses the solid electrolyte to make resistive element (U.S. Pat. No. 6,348,365). An opening is first formed in a proper layer, usually a dielectric layer. Then the solid electrolyte is filled in the opening. After that, a thin metallic layer is formed on the solid electrolyte resistive element. The metallic ions from the metal layer can enter the solid electrolyte resistive element under the certain electric field produced by the programming pulse current. It results in a change of the resistance of the solid electrolyte resistive element and realizes the information storage. Bigger the solid electrolyte resistive element, higher the programming energy is needed for the information storage.

To reduce the programming energy of these memories, it is desired that the size of the resistive element be as small as possible. The reduction of size of the resistive element is significant to reducing the programming energy of the memory. Considering a phase-change memory with a cubic resistive element, if the resistive element size is decreased 10 times smaller, then the volume of the resistive element will be 1000 times smaller. For example, if the resistive element decreases from the 0.2 μm (2000 Å) to 0.02 μm (200 Å), then the volume of the resistive element decreases from 8×10⁻³ μm³ to 8×10⁻⁶ m³. And it is also meant that the energy needed to program a memory will be also approximately 1000 times smaller.

The advantage of decreasing the resistive element size is not only the decrease of the programming energy, but also that making much faster and higher density memory becomes possible. Therefore, reduction of the resistive element size is a key for resistive memory to become a universal non-volatile memory and a potential candidate to replace the memories currently extensively used in the computer and telecommunication.

Since the resistive element is normally formed by filling the resistive element material in the opening of the dielectric layer which is sandwiched in a pair of electrodes, the size of the resistive element is essentially determined by the size of the opening. Therefore, to reduce the size of the resistive element essentially means to reduce the size of the opening. Currently, the opening is usually formed by the photolithography and etching processes. The reduction of opening size is limited by the resolution of the photolithography process. The typical minimum opening size that can be obtained by the current photolithography technique is in sub-micrometer, e.g., about 0.2 μm. This size basically determines the minimum resistive element size that can be achieved so far by the conventional photolithography and etching processes.

For the smaller resistive element size, some special techniques are needed. For example, in the U.S. Pat. No. 6,391,688 to Fernando, et al, it was reported that a very small opening with size from 50 to 500 Å can be made through some special thin film depositions and photolithography processes. But this method includes many processes and may cause high cost, difficulties to control the processes and may also result in low yield.

It is well known that when two different and unmixable materials are co-deposited onto a substrate, they normally form a composite-phase thin film with two separated phases containing each material. Herein that the two materials are unmixable means that these two materials are not soluble to each other and do not form an alloy containing these materials. In some cases, one material may form the extra-small particles embedded in another material, such as in the case of Fe/SiO₂ composite thin film (J. Applied Physics, Vol 84, 1998, p5693). Herein we call this particle as nano-dot particle because it has a size in the order of nanometer (1 nm=10⁻⁹ m=10 Å). In the present invention, we use this technique to fabricate ultra-small opening for filling resistive element material to make ultra-small resistive element for the memory application. The method of present invention is relatively simple and low-cost to make ultra small memory elements due to avoiding some complicated photolithography processes.

### SUMMARY OF THE INVENTION

An object of the present invention is to provide a new method to make ultra-small opening for the resistive memory element. It is also an object of the present invention to provide a method to make memory element with extra-small resistive element. This and other objects of present invention are accomplished by first making a composite-phase thin film with nano-dot particles embedded in a high resistive matrix layer. The materials of the nano-dot particle and high resistive matrix are chosen such that nano-dot particle is active chemically, while the high resistive matrix material is inactive chemically to some chemical or chemical solution. So the nano-dot particle can be etched away by the selected chemicals. The etching can be wet etching or dry etching. A nano-size opening was formed in the position of the particle after the particle was etched away. This opening can be then filled by the corresponding resistive material to make extra-small resistive element.

Since the resistive element made by the method of present invention can be as small as in nanometer scale, an ultra-low energy can heat such a resistive element to a very high temperature. Therefore, for the phase-change memory, the resistive element material is not necessary to be limited to some low melting point materials such as chalcogenide semiconductors. Some metals or alloys may be also used as resistive element material.

### BRIEF DESCRIPTION OF THE DRAWINGS

FIG. 1 is a cross sectional view illustrating a phase-change memory element with one resistive element layer made by the method of present invention.

FIG. 2 is a cross sectional view illustrating first electrode and composite-phase layer.

FIG. 3 is a simplified and enlarged perspective view illustrating the structure of composite-phase thin film.

FIG. 4 is a cross sectional view illustrating first electrode and composite-phase layer after the nano-dot particles were etched away. An opening was formed after the particle was etched.

FIG. 5 is a cross sectional view illustrating the memory structure after the phase-change resistive material was filled in the opening.

FIG. 6 shows ion mill process with some incident angle with resistive layer surface to mill away the resistive element material over the matrix layer.

FIG. 7 is a cross sectional view of the memory element after the resistive material over the matrix layer was milled away by the incident ion beam.

FIG. 8 is a cross sectional view of the PMCm memory after solid electrolyte material was filled in the opening and planerization by ion mill.

FIG. 9 shows ion mill process with ion beam perpendicular to layer surface to form a recession of solid electrolyte element from the matrix layer surface.

FIG. 10 is a cross sectional view of the PMCm memory after solid electrolyte resistive element forms a recession from the top surface of the matrix layer by the ion mill with ion beam perpendicular to the layer surface.

FIG. 11 is a cross sectional view of PMCm memory after the metallic layer was formed on the solid electrolyte element.

FIG. 12 is a cross sectional view of PMCm memory after top electrode layer and address line was formed.

FIG. 13 is a cross sectional view illustrating a phase-change memory cell with lamination of ultra-small resistive element layer and conductive layer.

FIG. 14 is a cross sectional view illustrating a PMCm memory cell with lamination of ultra-small resistive element layer and conductive layer.

FIG. 15 is a simplified and perspective view illustrating a portion of memory array with ultra-small resistive elements.

FIG. 16 is a general process flow diagram to make memory element with ultra-small resistive elements.

### DETAILED DESCRIPTION OF THE INVENTION

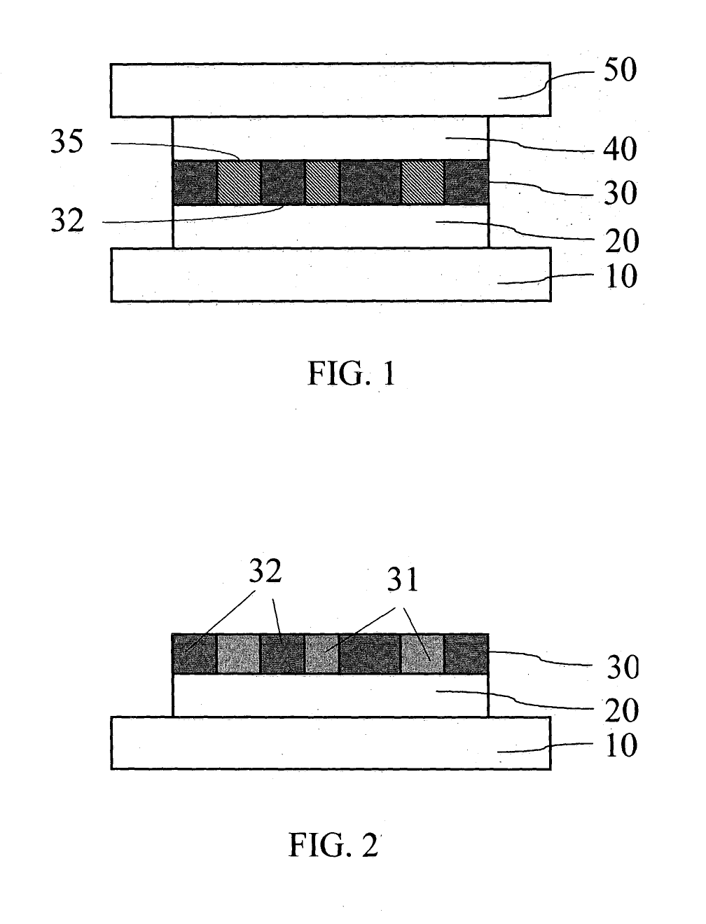

FIG. 1 is a cross sectional view illustrating a phase-change memory element structure with ultra small resistive elements. Basically, the memory element comprises of 3 layers: electrode layers 20 and 40, and resistive element layer 30. The resistive layer contains a plurality of extra-small resistive elements 35. The top surface and bottom surface of resistive element contacts with the electrode 20 and 40, and thus a single resistive element constitutes a resistor. The total resistance of all resistors basically determines the resistance value of a single memory element.

The electrode layers 20 and 40 are made of conductive material. The material of electrodes layer 20 and 40 should be chosen such that this material is not mixable with resistive layer materials, i.e., resistive element 35 and matrix layer 32. So the layer contacting with the resistive element 35 also functions as a barrier layer to prevent the atoms of the resistive element 35 and 32 from diffusion into the adjacent layers 20 and 40 and the atoms of the electrode layers 20 and 40 from diffusion to resistive layer 35 and 32. For the phase-change memory, since the information is stored by changing the resistance of the resistive element 35 through the heating by the programming pulse current, the material of the electrode layers 20 and 40 is preferred, but not limited to be the some high melting temperature metal, alloy or conductive compound such as carbide and nitride, for example, WC, TiN. The electrodes 20 and 40 can also be made by the multilayer thin film. In this case, the layer adjacent to the resistive layer 30 should also function as a barrier layer to prevent the diffusion of the atoms.

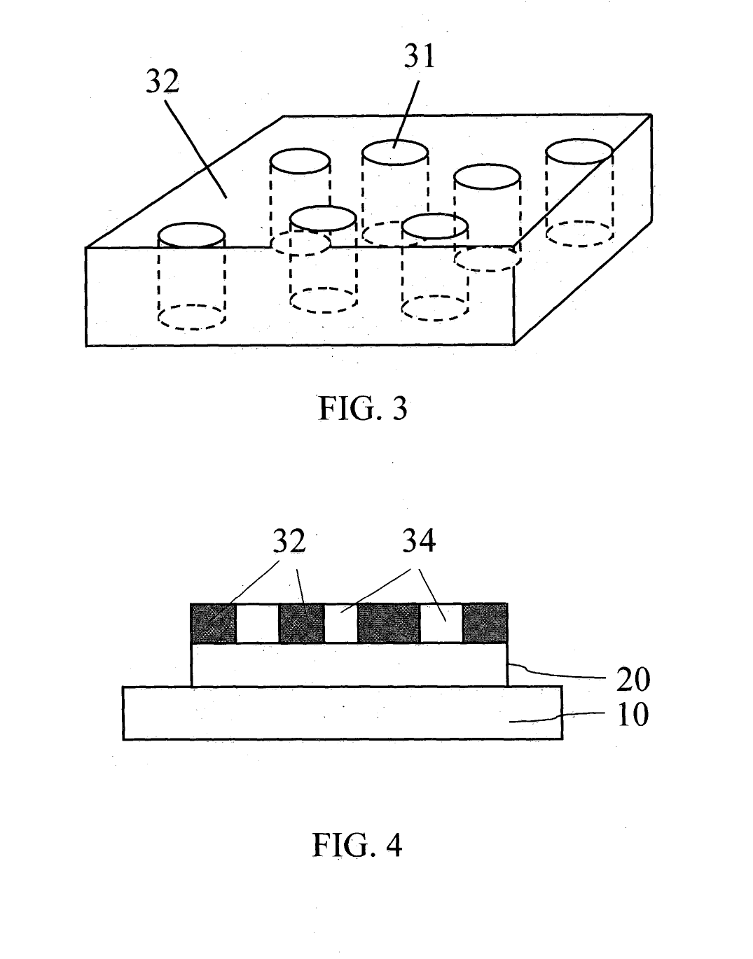

The resistive element 35 is made by filling the phase change material into an opening of the resistive layer 30. To make the opening, a composite-phase thin film 30 is first deposited on the first or bottom electrode layer 20, as shown in FIG. 2. The composite-phase thin film is a layer where one phase forms the ultra-small particles 31 and embedded uniformly in another phase which forms a matrix layer 32, as shown in FIG. 3. The thickness of composite-phase layer is in the range of about 1 nm to 100 nm.

The selection of the materials for the composite-phase thin film layer should meet following requirements: (a) the matrix layer material should be selected from a group of high resistive material so that programming current can mainly flow through the resistive elements; (b) the nano-dot particle material and matrix material are not mixable. It means that they are not soluble to each other and don't form an alloy when they come together by some means such as co-deposition of these two materials onto the same substrate; (c) nano-dot particle and high resistive matrix materials are chosen such that nano-dot particle is active chemically, while the high resistive matrix material is inactive chemically to some chemical or chemical solution. So the nano-dot particle can be etched away by the selected chemicals in the later process.

It is easy to find the materials meeting the above requirements. The oxide, nitride, boride, carbide, boron, silicon, carbon, carboxynitride and mixture of these materials are the good candidates for high resistive matrix material, while most metals and alloys are the good candidates for the nano-dot particle material. For example, Fe/SiO₂ is a good combination of these materials. Fe is conductive material, while SiO₂ is a high resistive material. Fe and SiO₂ are not mixable. When Fe and SiO₂ were co-deposited onto a substrate by some means such as sputtering, Fe forms very small particles which are uniformly embedded in the SiO₂ matrix layer under the certain deposition conditions. The SiO₂ is a very stable compound to most of chemicals such as acids, e.g. HCl, while Fe is active to most of acids, e.g. HCl. Since the Fe is active to HCl, while the SiO₂ is inactive to HCl, so the HCl is a suitable chemical solution to etch Fe particle and from a opening in SiO₂ matrix layer.

The size of the nano-dot particle is defined herein as the diameter of the particles, or their “characteristic dimension” which is equivalent to the diameter where the particles are not cylindrically shaped. The nano-dot particle size is about 1 nm to several tens nm, and more preferably of 3 nm to 50 nm.

Since the resistive element made by the method of present invention can be as small as in the nanometer scale, an extremely low energy can heat a resistive element to a very high temperature. Therefore, for the phase-change memory, the resistive element material is not necessary to be limited to some low melting temperature materials such as chalcogenide semiconductors. Some metals or alloys may be also used as resistive element material. For example, for a 5×5×5 nm nano-dot Cr particle, a 10 nanosecond current pulse of about 5.0×10⁻² mA can heat this particle to its melting temperature, i.e., 1890° C. The energy to melt this Cr particle is about 10⁻¹⁶ Joule, an extremely low energy. The resistance value of the Cr with size 5×5×5 nm in crystalline state is about 26 Ohms.

The composite-phase layer with nano-dot particles can be made by various thin film deposition methods such as sputtering, laser ablation, evaporation, or the chemical vapor deposition (CVD). The preferred and simple method is to co-sputter a composite target containing these two materials by the magnetron sputtering, RF sputtering or ion beam sputtering. By optimizing the deposition conditions and selecting suitable materials, a well-defined nano-dot particle 31 with desired size can be formed and embedded uniformly in the high resistive matrix layer 32. The composite-phase layer can also be made by the multi-layer thin film deposition of nano-dot particle material and matrix material. In this case, a several angstroms of high resistive matrix material and nano-dot particle material are deposited alternatively. After deposition, an anneal process maybe is necessary to form a composite-phase layer with well-defined nano-dot particles. To ensure the nano-dot particles are isolated by matrix material, the volume ratio of nano-dot material and matrix material in composite-phase layer should be less than about 3/1, typically, in the range of about 1/1˜1/100.

After forming the composite-phase layer, the nano-dot particles 31 are etched by choosing suitable chemicals. The etching process can be wet etching or dry etching. The dry etching means that the particles are etched by the plasma of some chemicals. The etching process doesn't etch the matrix. So after the particle was etched away completely, an opening 34 is formed and has the same size and shape as the particle 31, as shown in FIG. 4. After the nano-dot particles 31 are etched, the surface of the bottom electrode 20 is exposed so that the resistive element 35 can form a good electrical contact with the electrode 20 when it is filled in the opening 34.

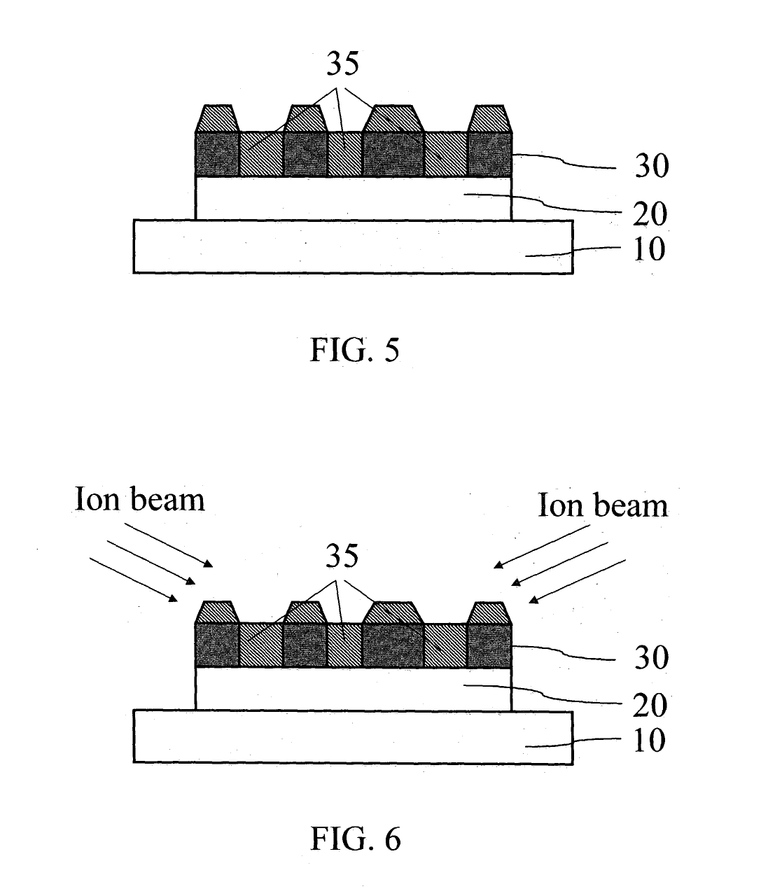

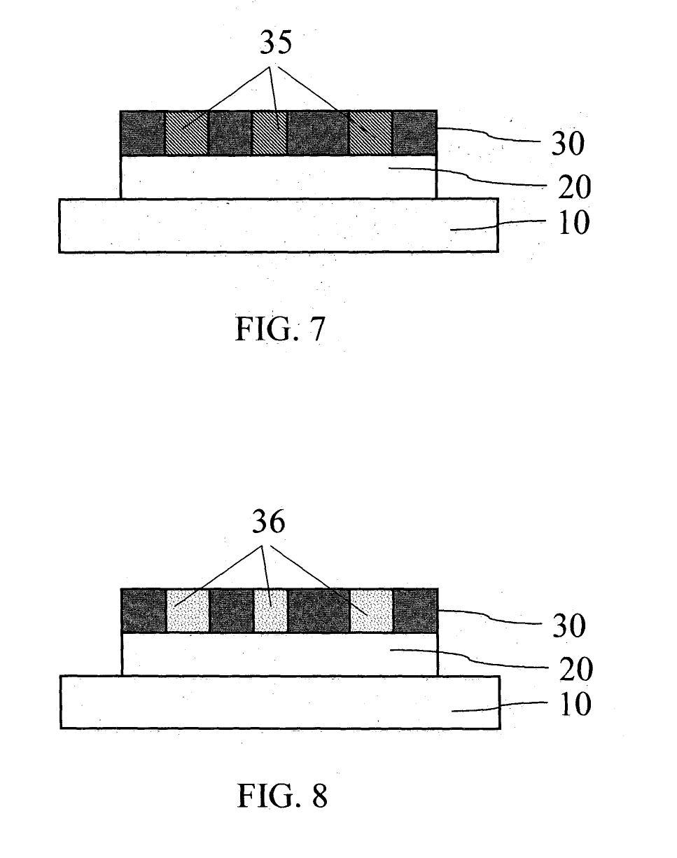

After forming the openings 34 in the position of the nano-dot particles, the resistive element materials such as phase-change material or solid electrolyte material can be filled in the openings to form an ultra-small resistive element. The filling of the resistive element material in the openings can be accomplished by the thin film deposition or the plating. For the thin film deposition, the resistive material will fill in the openings and also cover the surface of the matrix layer, as shown in FIG. 5. An ion mill process with some incident angle with the matrix layer surface can be used to mill away the resistive element material over the surface of the matrix layer, while the resistive element material inside the opening is still remained after the ion mill due to the shadowing effect, as shown in FIG. 6. FIG. 7 shows the phase-change memory element structure after the ion mill.

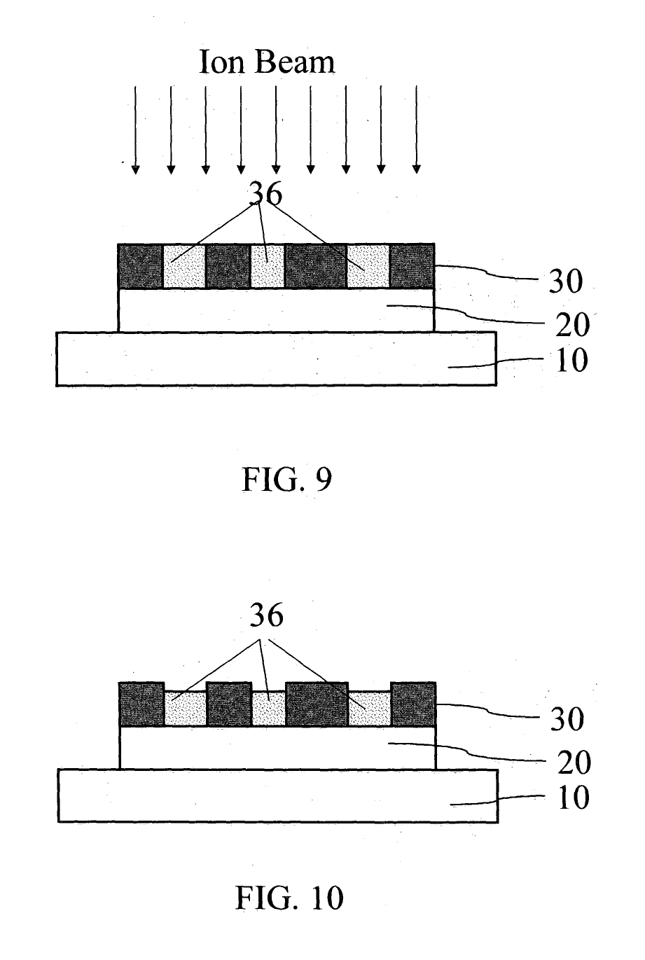

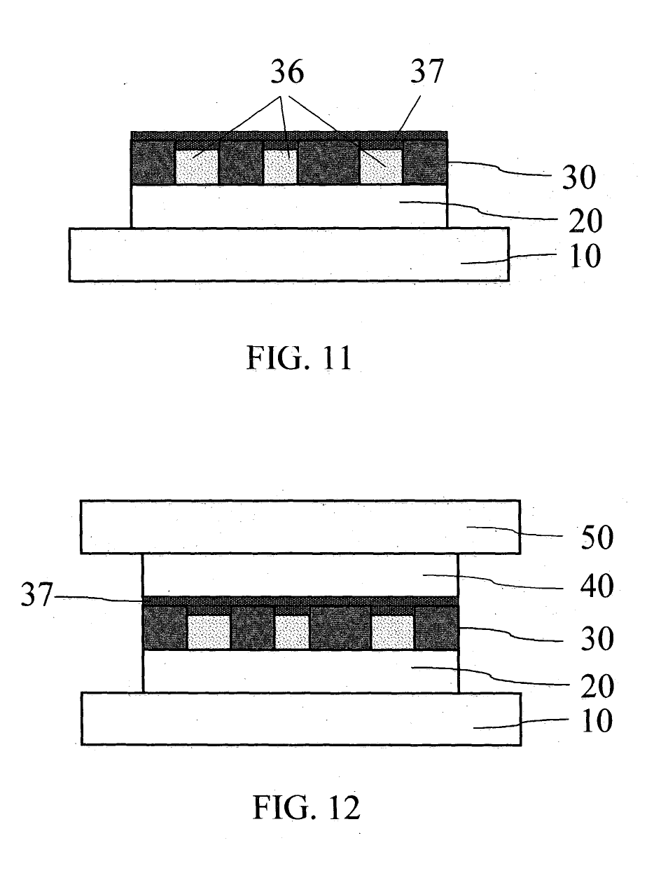

For the PMCm memory, after forming the opening 34 in the resistive layer 30, the electrolyte material is filled in the opening. As same as phase-change memory, electrolyte resistive element can be planerized by the ion mill with incident angle and is shown in FIG. 8. Then a recession of the electrolyte resistive element 36 from the surface of the matrix layer may be necessary and it can be realized by ion mill with ion beam perpendicular to the matrix surface, as shown in FIG. 9. Most high resistive materials such as oxide, nitride has much smaller etching rate than the most metals. So after ion mill, a recession will be formed for electrolyte resistive element and is shown in FIG. 10. After forming electrolyte element, a layer of metal 37 is deposited on the resistive element layer 30, as shown in FIG. 11.

After forming the resistive layer 30 for the phase-change memory or after forming metallic layer 37 for the PMCm memory, the second electrode 40 was formed on the resistive layer 30, as seen in FIG. 1, or on the metal layer 37 for the PMCm memory, as seen in FIG. 12.

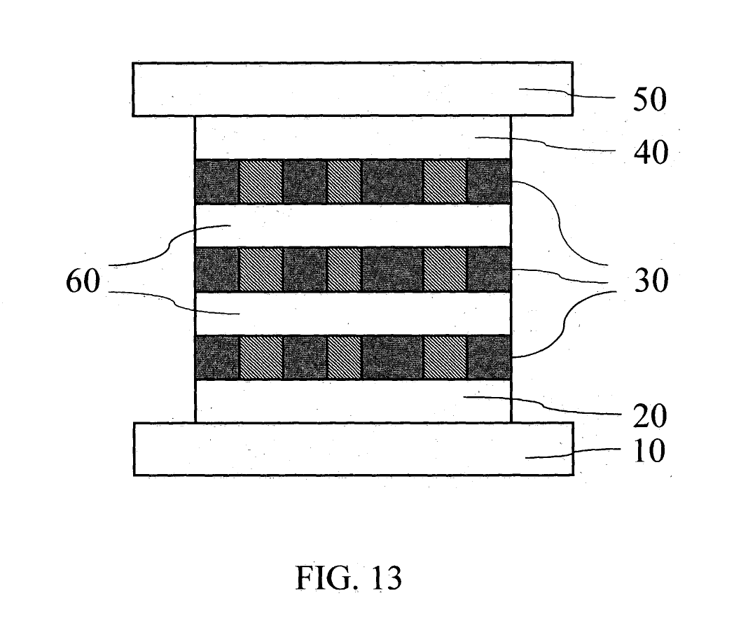

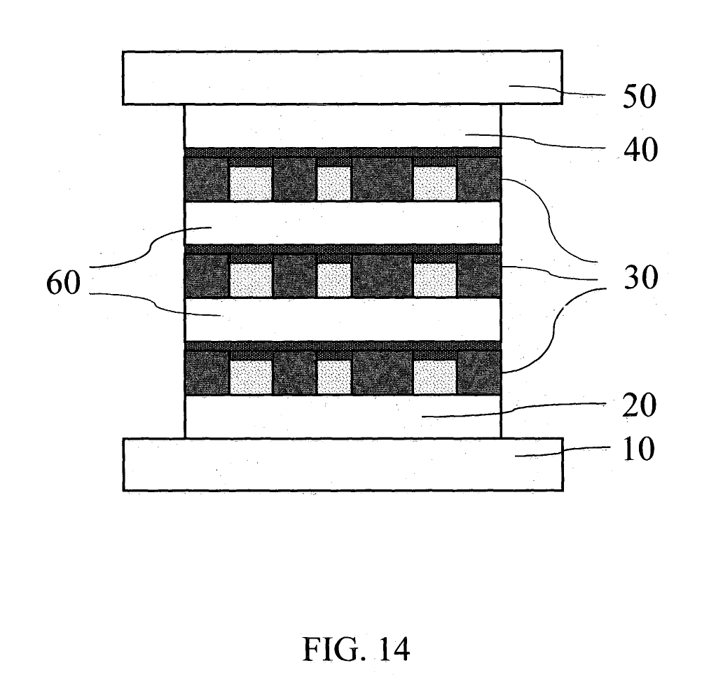

The resistance of the memory element can be changed by using a lamination of resistive layer and conductive layer. A phase-change memory element structure with lamination of resistive layer and conductive layer is shown in FIG. 13. The selection role for the conductive 60 is the same as electrode layers 20 and 40. The advantages of laminated resistive layer memory element are improved uniformity of the resistance of each memory element and to obtain a desired resistance value. These advantages are especially of importance when the memory element size becomes substantially smaller for the extra-high density memory. Since the number of the resistive elements 35 in a single layer decreases with the memory element size if the size of the resistive element is constant. The less is the number of the resistive elements, the poorer is the uniformity of the resistance of the memory element. For example, if there is only one resistive element in single resistive layer, the resistance of each memory element may change with the size of the resistive element since the there is some variation in resistive element size. So it is necessary to have certain number of the resistive elements 34 in a single memory to ensure a uniform resistance distribution among the memory elements. As same as phase-change memory, by repeating the resistive layer 30, metallic layer 37 and conductor layer 60, we can also make PMCm memory with lamination of resistive layer and conductor layer, as shown in FIG. 14.

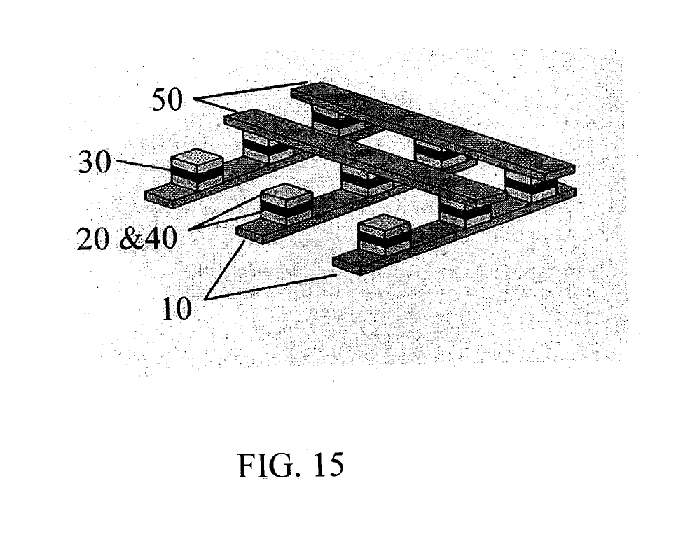

As any conventional memory element, the present memory elements including the phase-change memory or PMCm memory can be incorporated into the construction of very dense two-dimensional and three-dimensional memory arrays. FIG. 15 shows a portion of two-dimensional memory array with extra-small resistive elements. The memory element including a ultra-small resistive layer 30 and electrode layer 20 and 40 is sandwiched between the address lines. Here we define the bottom address line as X address line and top address line as Y address line.

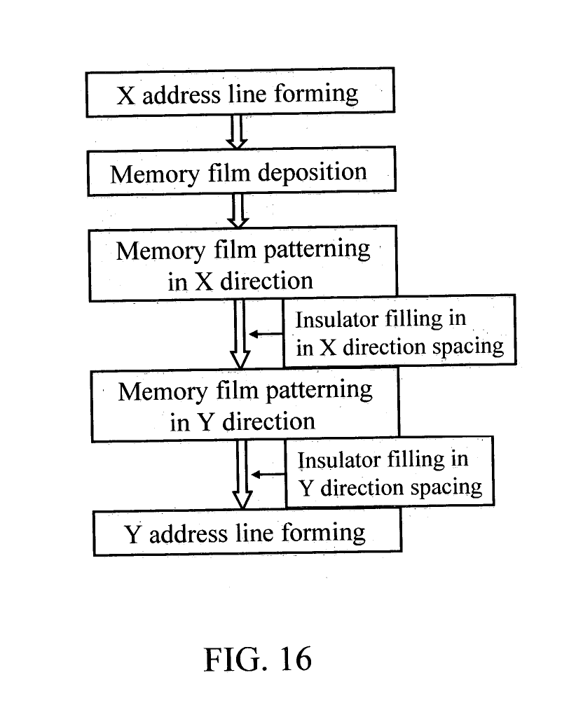

A general procedure of fabricating the present memory elements is showed in FIG. 16. To better control the processes, it is preferred that the whole memory element layer stack including electrodes and resistive element be finished in a multi-function system with sputtering, ion mill and plasma dry etching. After forming the X address lines 10, the first electrode and composite-phase layer were deposited. And then the composite-phase layer was etched by the plasma. The etching process only etches the nano-dot particles. After etching, ultra-small openings were formed. And then the resistive element material was filled in the openings by the method of thin film deposition. After milling away resistive element material over the matrix layer or forming the thin metallic layer for PMCm memory, the second electrode layer 40 is formed on the resistive layer.

After forming all memory layer stack including electrodes, resistive element layers on a substrate, the layer stack then can be patterned by the conventional methods of photolithography and etching processes. To obtain an approximate square memory element, the layer stack needs to be patterned in X direction and Y direction, i.e., first forming a stripe in X direction and then forming an approximately square memory element by patterning in Y direction. An insulator should be filled in the spacing between the memory elements in the X and Y directions. After forming the memory element, the Y address lines 50 are built on the memory elements. Although not shown here, as conventional memories, some circuits need to be accomplished before and after fabricating memory elements to isolate the each memory element for reading and writing.

What is claim is:

1. A method of fabricating extra-small openings comprising the steps of:
a. forming a composite-phase thin film layer where one phase forms extra-small particles and embedded in another phase which forms a matrix layer;
b. removing the phase which forms the extra-small particles.

2. The thickness of the composite-phase thin film in claim 1 is in the range of about 1 to 100 nm.

3. The size of the said extra-small particle is in the range of about 1 to 100 nm.

4. The volume ratio of the said nano-dot particle phase and the said matrix layer is in the range of about 3:1 to 1:200.

5. The materials of two phases in claim 1 are not mixable.

6. The material of the phase in claim 1 which forms ultra-small particles is active to some chemical, while another phase in claim 1 which forms matrix layer is inactive to the chemical.

7. The materials of the phase in claim 1 which form matrix layer is one or more materials selected from the oxide, nitride, boride, carbide, boron, silicon, carbon, carboxynitride and mixture thereof.

8. A phase-change memory device comprising:
a. a pair of electrodes; and
b. a resistive layer with a plurality of ultra-small resistive element, or
c. a lamination of said resistive layer and conductive layer.

9. The extra-small resistive element in claim 8 is formed by filling the phase-change resistive element material in the opening formed by the method of claim 1.

10. The top surface and bottom surface of the said resistive elements in claim 8 contacts directly with the top and bottom electrodes, respectively.

11. The device in claim 8 with lamination of resistive layer and conductive layer wherein the top surface and bottom surface contact with said adjacent conductor layer.

12. The device of claim 8 wherein the resistive layer has a thickness in the range of about 1.0 to 100 nm.

13. The device of claim 8 wherein the size of the resistive element is in the range of about 1.0-100 nm in diameter.

14. The device of claim 8 wherein the material of electrode layer and the conductive layer in the lamination resistive element is selected from the high melting temperature metals, alloys and conductive compounds.

15. The programming of the device of claim 8 includes a pulse current of short duration and higher current and a pulse current with longer duration and lower current.

16. A programming metallization cell memory (PMCm) comprising:
a. a pair of electrodes; and
b. a thin metal layer; and
c. a single resistive layer with a plurality of ultra-small solid electrolyte resistive element, or
d. a lamination of said resistive layer, thin metal layer and conductive layer.

17. The said extra-small solid electrolyte resistive element in claim 16 is formed by filling the solid electrolyte resistive element material in the opening formed by the method of claim 1.

18. The top surface and bottom surface of the said solid electrolyte resistive elements in the claim 16 contact directly with the adjacent metal layer and bottom electrode, respectively.

19. The device of claim 16 with lamination of resistive layer, thin metal layer and conductive layer wherein the top surface and bottom surface of said solid electrolyte element contact with adjacent said conductor layer and thin metal layer.

20. The device of claim 16 wherein the size of the solid electrolyte resistive element is in the range of about 1.0-100 nm in diameter.
